(19) United States
(12) Patent Application Publication
(10) Pub. No.: US 2018/0265707 A1
(43) Pub. Date: Sep. 20, 2018

(54) DICHROIC DYE COMPOUND, DICHROIC DYE COMPOSITION, LIGHT-ABSORBING ANISOTROPIC FILM, POLARIZING ELEMENT, AND IMAGE DISPLAY DEVICE

(71) Applicant: FUJIFILM Corporation, Tokyo (JP)

(72) Inventors: Masatoshi MIZUMURA, Minami-ashigara-shi (JP); Takashi KATOU, Minami-ashigara-shi (JP)

(73) Assignee: FUJIFILM Corporation, Tokyo (JP)

(21) Appl. No.: 15/986,982

(22) Filed: May 23, 2018

Related U.S. Application Data
(63) Continuation of application No. PCT/JP2016/084767, filed on Nov. 24, 2016.

(30) Foreign Application Priority Data
Nov. 24, 2015 (JP) 2015-229008

(51) Int. Cl. C09B 31/14; G02F 1/1337; G02F 1/1335; G02B 5/30

(52) U.S. Cl. CPC C09B 31/14; G02F 1/133711; H01L 51/5284; G02B 5/305; G02F 1/133528

(57) ABSTRACT

An object of the invention is to provide a dichroic dye compound which maintains an excellent degree of polarization in a case of being used in a polarizing element and has satisfactory solubility; a dichroic dye composition; a light-absorbing anisotropic film; a polarizing element; and an image display device. The dichroic dye compound of the invention is a dichroic dye compound having a structure represented by Formula (I).

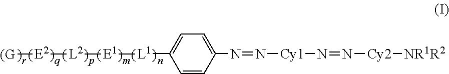

In Formula (I), L¹ and L² each independently represent a divalent aliphatic hydrocarbon group which may have a substituent or a heteroatom; E¹ and E² each independently represent —O(C═O)— or —(C═O)O—; G represents a branched monovalent aliphatic hydrocarbon group; n, m, p, q, and r each independently represent 0 or 1; and the sum of m, q, and r represents 2 or 3, provided that in a case in which the sum of m and q is 2, G represents a linear or branched monovalent aliphatic hydrocarbon group.

### CROSS-REFERENCE TO RELATED APPLICATIONS

This application is a Continuation of PCT International Application No. PCT/JP2016/084767 filed on Nov. 24, 2016, which claims priority under 35 U.S.C. § 119(a) to Japanese Patent Application No. 2015-229008 filed on Nov. 24, 2015. The above application is hereby expressly incorporated by reference, in its entirety, into the present application.

### BACKGROUND OF THE INVENTION

### 1. Field of the Invention

The present invention relates to a dichroic dye compound, a dichroic dye composition, a light-absorbing anisotropic film, a polarizing element, and an image display device.

### 2. Description of the Related Art

In the related art, in a case in which an attenuating function, a polarizing function, a scattering function, a light-shielding function, and the like for illuminated light including laser light or natural light are needed, apparatuses operating based on different principles for the respective functions have been utilized. Therefore, products corresponding to the above-described functions have also been produced by different production processes depending on the respective functions.

For example, in liquid crystal displays (LCDs), linear polarizing plates or circularly polarizing plates are used in order to control optical activity or birefringence in the process of display. Furthermore, also in organic light emitting diodes (OLEDs), circularly polarizing plates are used in order to prevent reflection of external light.

In the related art, in these polarizing plates (polarizing elements), iodine has been widely used as a dichroic substance. However, polarizing elements that use organic dyes as dichroic substances instead of iodine have also been investigated.

For example, in JP2011-237513A, “a light-absorbing anisotropic film containing at least one thermotropic liquid crystalline dichroic dye and at least one thermotropic liquid crystalline polymer, in which the mass content of the thermotropic liquid crystalline dichroic dye in the light-absorbing anisotropic film is 30% or more,” is described ([Claim 1]).

### SUMMARY OF THE INVENTION

The inventors of the present invention conducted an investigation on the light-absorbing anisotropic film described in JP2011-237513A, and it was found that although the light-absorbing anisotropic film exhibits a high degree of polarization and a satisfactory nature, the light-absorbing anisotropic film has low solubility in a solvent depending on the type of the thermotropic liquid crystalline dichroic dye, and for example, the light-absorbing anisotropic film may not dissolve in cyclopentanone, which has high coating adaptability.

Thus, an object of the invention is to provide a dichroic dye compound which maintains an excellent degree of polarization in a case of being used in a polarizing element and has satisfactory solubility, a dichroic dye composition, a light-absorbing anisotropic film, a polarizing element, and an image display device.

The inventors conducted a thorough investigation in order to achieve the object described above, and as a result, the inventors found that in a case in which a dichroic dye compound having a particular structure is used, satisfactory solubility is obtained, and a polarizing element can maintain an excellent degree of polarization, thus completing the invention.

That is, the inventors found that the object described above can be achieved by the following configuration.

[1] A dichroic dye compound having a structure represented by Formula (I):

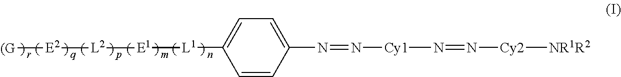

in Formula (I),

L¹ and L² each independently represent a divalent aliphatic hydrocarbon group which may have a substituent or a heteroatom;

E¹ and E² each independently represent an ester bond represented by —O(C═O)— or —(C═O)O—;

G represents a branched monovalent aliphatic hydrocarbon group;

n, m, p, q, and r each independently represent 0 or 1, and the sum of m, q, and r represents 2 or 3, provided that in a case in which the sum of m and q is 2, G represents a linear or branched monovalent aliphatic hydrocarbon group;

Cy1 and Cy2 each independently represent a divalent aromatic hydrocarbon group or a divalent aromatic heterocyclic group, both of which may have a substituent; and

R¹ and R² each independently represent an alkyl group which may have a substituent.

[2] The dichroic dye compound according to [1], wherein in Formula (I), Cy1 and Cy2 each independently represent a phenylene group or a divalent aromatic heterocyclic group, both of which may have a substituent.

[3] The dichroic dye compound according to [1] or [2], wherein in Formula (I), r is 1.

[4] The dichroic dye compound according to any one of [1] to [3], wherein in Formula (I), L¹ and L² each independently represent an alkylene group having 1 to 10 carbon atoms.

[5] The dichroic dye compound according to any one of [1] to [4], wherein in Formula (I), G has a methyl group or an ethyl group as a substituent, and the monovalent aliphatic hydrocarbon group is an alkyl group having 3 to 12 carbon atoms.

[6] The dichroic dye compound according to any one of [1] to [5], wherein in Formula (I), Cy1 represents a divalent aromatic heterocyclic group, and Cy2 represents a phenylene group.

[7] The dichroic dye compound according to any one of [1] to [6], wherein in Formula (I), Cy1 represents a divalent aromatic heterocyclic group in which two 5-membered heterocyclic rings are fused.

[8] A dichroic dye composition comprising the dichroic dye compound according to any one of [1] to [7].

[9] The dichroic dye composition according to [8], further comprising another dichroic dye compound.

[10] The dichroic dye composition according to [8] or [9], wherein two or more kinds of the dichroic dye compounds according to any one of [l] to [7] are contained.

[11] The dichroic dye composition according to any one of [8] to [10], further comprising a horizontal aligning agent.

[12] A light-absorbing anisotropic film formed using the dichroic dye composition according to any one of [8] to [11].

[13] A polarizing element comprising: an alignment film; and the light-absorbing anisotropic film according to [12] provided on the alignment film.

[14] An image display device comprising the light-absorbing anisotropic film according to [12], or the polarizing element according to [13].

According to the invention, a dichroic dye compound which maintains an excellent degree of polarization in a case of being used in a polarizing element, and has satisfactory solubility, a dichroic dye composition, a light-absorbing anisotropic film, a polarizing element, and an image display device can be provided.

### DESCRIPTION OF THE PREFERRED EMBODIMENTS

In the following description, the invention will be explained in detail.

The explanation of the configuration requirements described below may be based on representative embodiments of the invention; however, the invention is not intended to be limited to such embodiments.

According to the present specification, a numerical value range indicated using the symbol “˜” means a range including the numerical values described before and after the symbol “˜” as the lower limit and the upper limit, respectively.

[Dichroic Dye Compound]

The dichroic dye compound of the invention is a dichroic dye compound having a structure represented by Formula (I):

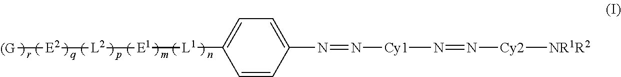

Here, in Formula (I), L¹ and L² each independently represent a divalent aliphatic hydrocarbon group which may have a substituent or a heteroatom.

E¹ and E² each independently represent an ester bond represented by —O(C═O)— or —(C═O)O—.

G represents a branched monovalent aliphatic hydrocarbon group.

n, m, p, q, and r each independently represent 0 or 1, and the sum of m, q, and r represents 2 or 3. However, in a case in which the sum of m and q is 2, G represents a linear or branched monovalent aliphatic hydrocarbon group.

Cy1 and Cy2 each independently represent a divalent aromatic hydrocarbon group or a divalent aromatic heterocyclic group, both of which may have a substituent.

R¹ and R² each independently represent an alkyl group which may have a substituent.

The dichroic dye compound of the invention acquires satisfactory solubility by having a structure represented by Formula (I) described above, and can maintain an excellent degree of polarization in a case of being used in a polarizing element.

This is not clearly understood in detail; however, the inventors speculate as follows.

The inventors considered that in a case in which in Formula (I), the sum of m, q, and r is an integer of 2 or greater, that is, in a case in which a dichroic dye compound has two or more structures selected from the group consisting of an ester bond represented by E¹ in Formula (I), an ester bond represented by E² in Formula (I), and a branched monovalent aliphatic hydrocarbon group represented by G in Formula (I), the solubility in a polar solvent such as cyclopentanone has increased. Specifically, in a case in which the dichroic dye compound has an ester bond, it is considered to be caused by the fact that polarizability of the molecule increases, and thereby the affinity with a polar solvent also increases. In a case in which the dichroic dye compound has a branched monovalent aliphatic hydrocarbon group, it is considered to be caused by the fact that compact overlapping between molecules is inhibited, and the molecules of the dichroic dye compound can easily interact with solvent molecules.

The “divalent aliphatic hydrocarbon group which may have a substituent or a heteroatom” represented by L¹ and L² in the above-described Formula (I) will be explained.

Examples of the substituent include an alkyl group and an alkoxy group. The alkyl group is preferably a linear, branched, or cyclic alkyl group having 1 to 18 carbon atoms, and an alkyl group having 1 to 8 carbon atoms (for example, methyl, ethyl, propyl, isopropyl, n-butyl, isobutyl, sec-butyl, t-butyl, or cyclohexyl) is more preferred. The alkoxy group is preferably an alkoxy group having 1 to 18 carbon atoms, and an alkoxy group having 1 to 8 carbon atoms (for example, methoxy, ethoxy, n-butoxy, or methoxyethoxy) is more preferred.

Examples of the heteroatom include an oxygen atom, a nitrogen atom, and a sulfur atom. An embodiment having a heteroatom is an embodiment in which a divalent aliphatic hydrocarbon group partially contains a structure such as —O—, —S—, —SO₂—, —SO₃—, or —NR— (wherein R represents hydrogen or an alkyl group).

Examples of the divalent aliphatic hydrocarbon group include an alkylene group having 1 to 10 carbon atoms, a cycloalkylene group having 3 to 10 carbon atoms, and a group combining a plurality of these groups.

Specific examples of the alkylene group having 1 to 10 carbon atoms include a methylene group, an ethylene group, a propylene group, a butylene group, a pentylene group, a hexylene group, an octylene group, and a decylene group, and above all, a methylene group, an ethylene group, or a propylene group is preferred.

Specific examples of the cycloalkylene group having 3 to 10 carbon atoms include a cyclohexylene group and a cyclopentylene group, and above all, a cyclohexylene group is preferred.

Among these, the divalent aliphatic hydrocarbon group is preferably an alkylene group having 1 to 10 carbon atoms.

The “ester bond” represented by E¹ and E² in Formula (I) will be explained.

In regard to the ester bond, the direction of the bond is not particularly limited, and the ester bond may be any of —O(C═O)— and —(C═O)O—.

The “branched monovalent aliphatic hydrocarbon group” represented by G in Formula (I) will be explained.

Here, a branched form means an embodiment in which a linear monovalent aliphatic hydrocarbon group that constitutes the main skeleton has a substituent such as a monovalent aliphatic hydrocarbon group as a branched chain.

The substituent that constitutes the branched chain may be, for example, a linear, branched, or cyclic alkyl group having 1 to 8 carbon atoms. Among them, a linear alkyl group having 1 to 6 carbon atoms is preferred, a linear alkyl group having 1 to 3 carbon atoms is more preferred, and a methyl group or an ethyl group is even more preferred.

Regarding the substituent that constitutes the branched chain, the monovalent aliphatic hydrocarbon group may have a plurality of the substituents on one carbon atom that constitutes the aliphatic hydrocarbon group of the main skeleton, or may have a plurality of the substituents separately on two or more carbon atoms.

Regarding the monovalent aliphatic hydrocarbon group (main skeleton in a linear form) excluding the substituent described above, in a case in which the monovalent aliphatic hydrocarbon group has an alkyl group as the substituent, it is preferable that the monovalent aliphatic hydrocarbon group is an alkyl group having a larger number of carbon atoms than the number of carbon atoms of the alkyl group as the substituent.

Regarding such a monovalent aliphatic hydrocarbon group, in a case in which the substituent that constitutes the branched chain is a methyl group or an ethyl group, an alkyl group having 3 to 12 carbon atoms is preferred; an alkyl group having 4 to 10 carbon atoms is more preferred; and a butyl group, a pentyl group, a hexyl group, a heptyl group, an octyl group, a nonyl group, and a decyl group are even more preferred.

According to the invention, in a case in which the sum of m and q in Formula (I) is 2, G in Formula (I) may be any of the branched monovalent aliphatic hydrocarbon group described above and a linear monovalent aliphatic hydrocarbon group (main skeleton in a linear form as described above).

In Formula (I), n, m, p, q, and r each independently represent 0 or 1 as described above, and the sum of m, q, and r represents 2 or 3.

According to the invention, an embodiment in which r is 1, that is, an embodiment in which the dichroic dye compound has the “branched monovalent aliphatic hydrocarbon group” represented by G is preferred, for the reason that solubility of the dichroic dye compound is further increased.

The “divalent aromatic hydrocarbon group or divalent aromatic heterocyclic group, both of which may have a substituent” represented by Cy1 and Cy2 in Formula (I) will be explained.

Regarding the substituent described above, for example, the Substituent Group G described in paragraphs [0237] to [0240] of JP2011-237513A may be mentioned, and above all, suitable examples include a halogen atom, an alkyl group, an alkoxy group, an alkoxycarbonyl group (for example, methoxycarbonyl or ethoxycarbonyl), and an aryloxycarbonyl group (for example, phenoxycarbonyl, 4-methylphenoxycarbonyl, or 4-methoxyphenylcarbonyl).

The divalent aromatic hydrocarbon group may be, for example, an arylene group having 6 to 12 carbon atoms, and specific examples include a phenylene group, a cumenylene group, a mesitylene group, a tolylene group, and a xylyene group. Among them, a phenylene group is preferred.

The divalent aromatic heterocyclic group is preferably a group derived from a monocyclic or bicyclic heterocyclic ring. Examples of an atom other than carbon, which constitutes the aromatic heterocyclic group, include a nitrogen atom, a sulfur atom, and an oxygen atom. In a case in which the aromatic heterocyclic group has a plurality of ring-constituting atoms other than carbon, these atoms may be identical or different. Specific examples of the divalent aromatic heterocyclic group include a pyridylene group (pyridine-diyl group), a quinolylene group (quinolone-diyl group), an isoquinolylene group (isoquinoline-diyl group), a benzothiadiazole-diyl group, a phthalimide-diyl group, and a thienothiazole-diyl group (hereinafter, referred to as “thienothiazole group”). Among them, the divalent aromatic heterocyclic group is preferably a divalent aromatic heterocyclic group fused with a 5-membered heterocyclic ring, and a thienothiadiazole group is particularly preferred.

Among these, it is preferable that in Formula (I), Cy1 represents a divalent aromatic heterocyclic group, and Cy2 represents a phenylene group; and it is more preferable that Cy1 represents a divalent aromatic heterocyclic group in which two 5-membered heterocyclic rings are fused, and Cy2 represents a phenylene group.

The “alkyl group which may have a substituent” represented by R¹ and R² in Formula (I) will be explained.

The substituent may be, for example, a halogen atom.

The alkyl group may be a linear, branched, or cyclic alkyl group having 1 to 8 carbon atoms. Among them, a linear alkyl group having 1 to 6 carbon atoms is preferred, a linear alkyl group having 1 to 3 carbon atoms is more preferred, and a methyl group or an ethyl group is even more preferred.

Specific examples of the dichroic dye compound having a structure represented by Formula (I) include compounds represented by Formulae (1) to (5).

Here, the compounds represented by Formulae (1) to (5) are all examples in which Cy1 in Formula (I) is a thienothiazole group; Cy2 is a phenylene group; and R¹ and R² are both an ethyl group.

Meanwhile, synthesis methods or these compounds are as disclosed in the Examples given below.

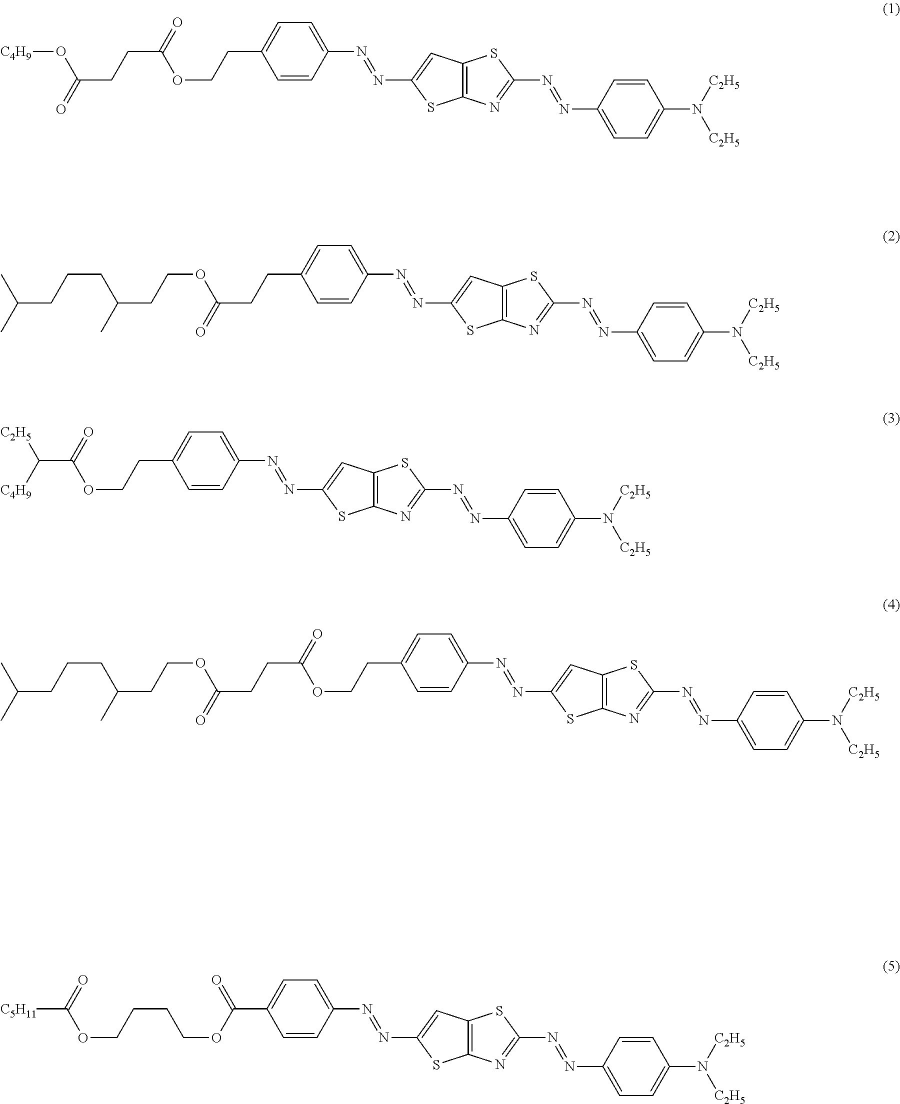

[Dichroic Dye Composition]

The dichroic dye composition of the invention is a coloring composition including one kind or two or more kinds of the dichroic dye compounds of the invention described above.

In the following description, optional components other than the dichroic dye compound, which are included in the dichroic dye composition of the invention, will be described in detail.

[Other Dichroic Dye Compounds]

The dichroic dye composition of the invention may include another dichroic dye compound in addition to the dichroic dye compound of the invention described above.

Examples of the other dichroic dye compounds include an azo-based dye, a cyanine-based dye, an azo-metal complex, a phthalocyanine-based dye, a pyrylium-based dye, a perylene-based dye, an anthraquinone-based dye, a squarylium-based dye, a quinone-based dye, a triphenylmethane-based dye, and a triarylmethane-based dye. Among the dyes described above, it is preferable to use a compound having a maximum absorption wavelength of 400 to 600 nm.

The other dichroic dye compound is preferably a compound represented by Formula (II) or Formula (III).

Ar₁₄—N═N—Ar₁₃-L₃-Ar₁₂—N═N—Ar₁₁ Formula (II)

In Formula (II), Ar₁₁, Ar₁₂, Ar₁₃, and Ar₁₄ each independently represent an aromatic hydrocarbon group which may have a substituent, or a heterocyclic group which may have a substituent; and L₃ represents a divalent linking group.

Ar₁₆—N═N—Ar₁₅. Formula (II)

In Formula (III), Ar₁₅ and Ar₁₆ each independently represent an aromatic hydrocarbon group which may have a substituent, or a heterocyclic group which may have a substituent.

Regarding Ar₁₁, Ar₁₂, Ar₁₃, Ar₁₄, Ar₁₅, and Ar₁₆, a phenyl group which may have a substituent, a naphthyl group which may have a substituent, or a heterocyclic group which may have a substituent is preferred. The substituent is preferably a group that is introduced in order to increase the solubility or nematic liquid crystallinity of an azo compound; a group having electron donating properties or electron withdrawing properties, which is introduced in order to regulate the tone as a dye; or a group having a polymerizable group, which is introduced in order to fix the alignment. Examples of the substituent include an alkyl group (preferably an alkyl group having 1 to 20 carbon atoms, more preferably 1 to 12 carbon atoms, and particularly preferably 1 to 8 carbon atoms; and examples include a methyl group, an ethyl group, an isopropyl group, a tert-butyl group, a n-octyl group, a n-decyl group, a n-hexadecyl group, a cyclopropyl group, a cyclopentyl group, and a cyclohexyl group), an alkenyl group (preferably an alkenyl group having 2 to 20 carbon atoms, more preferably 2 to 12 carbon atoms, and particularly preferably 2 to 8 carbon atoms; and examples include a vinyl group, an allyl group, a 2-butenyl group, and a 3-pentenyl group), an alkynyl group (preferably an alkynyl group having 2 to 20 carbon atoms, more preferably 2 to 12 carbon atoms, and particularly preferably 2 to 8 carbon atoms; and examples include a propargyl group and a 3-pentynyl group), an aryl group (preferably an aryl group having 6 to 30 carbon atoms, more preferably 6 to 20 carbon atoms, and particularly preferably 6 to 12 carbon atoms; and examples include a phenyl group, a 2,6-diethylphenyl group, a 3,5-ditrifluoromethylphenyl group, a naphthyl group, and a biphenyl group), a substituted or unsubstituted amino group (preferably an amino group having 0 to 20 carbon atoms, more preferably 0 to 10 carbon atoms, and particularly preferably 0 to 6 carbon atoms; and examples include an unsubstituted amino group, a methylamino group, a dimethylamino group, a diethylamino group, and an anilino group), an alkoxy group (preferably having 1 to 20 carbon atoms, more preferably 1 to 10 carbon atoms, and particularly preferably 1 to 6 carbon atoms; and examples include a methoxy group, an ethoxy group, and a butoxy group), an oxycarbonyl group (preferably having 2 to 20 carbon atoms, more preferably 2 to 15 carbon atoms, and particularly preferably 2 to 10 carbon atoms; and examples include a methoxycarbonyl group, an ethoxycarbonyl group, and a phenoxycarbonyl group), an acyloxy group (preferably having 2 to 20 carbon atoms, more preferably 2 to 10 carbon atoms, and particularly preferably 2 to 6 carbon atoms; and examples include an acetoxy group and a benzoyloxy group), an acylamino group (preferably having 2 to 20 carbon atom, more preferably 2 to 10 carbon atoms, and particularly preferably 2 to 6 carbon atoms; and examples include an acetylamino group and a benzoylamino group), an alkoxycarbonylamino group (preferably having 2 to 20 carbon atoms, more preferably 2 to 10 carbon atom, and particularly preferably 2 to 6 carbon atoms; and examples include a methoxycarbonylamino group), an aryloxycarbonylamino group (preferably having 7 to 20 carbon atoms, more preferably 7 to 16 carbon atoms, and particularly preferably 7 to 12 carbon atoms; and examples include a phenyloxycarbonylamino group), a sulfonylamino group (preferably having 1 to 20 carbon atoms, more preferably 1 to 10 carbon atoms, and particularly preferably 1 to 6 carbon atoms; and examples include a methanesulfonylamino group and a benzenesulfonylamino group), a sulfamoyl group (preferably having 0 to 20 carbon atoms, more preferably 0 to 10 carbon atoms, and particularly preferably 0 to 6 carbon atoms; and examples include a sulfamoyl group, a methylsulfamoyl group, a dimethylsulfamoyl group, and a phenylsulfamoyl group), a carbamoyl group (preferably having 1 to 20 carbon atoms, more preferably 1 to 10 carbon atoms, and particularly preferably 1 to 6 carbon atoms; and examples include an unsubstituted carbamoyl group, a methylcarbamoyl group, a diethylcarbamoyl group, and a phenylcarbamoyl group), an alkylthio group (preferably having 1 to 20 carbon atoms, more preferably 1 to 10 carbon atoms, and particularly preferably 1 to 6 carbon atoms; and examples include a methylthio group and an ethylthio group), an arylthio group (preferably having 6 to 20 carbon atoms, more preferably 6 to 16 carbon atoms, and particularly preferably 6 to 12 carbon atoms; and examples include a phenylthio group), a sulfonyl group (preferably having 1 to 20 carbon atoms, more preferably 1 to 10 carbon atoms, and particularly preferably 1 to 6 carbon atoms; and examples include a mesyl group and a tosyl group), a sulfinyl group (preferably having 1 to 20 carbon atoms, more preferably 1 to 10 carbon atoms, and particularly preferably 1 to 6 carbon atoms; and examples include a methanesulfinyl group and a benzenesulfinyl group), a ureido group (preferably having 1 to 20 carbon atoms, more preferably 1 to 10 carbon atoms, and particularly preferably 1 to 6 carbon atoms; and examples include an unsubstituted ureido group, a methylureido group, and a phenylureido group), a phosphoric acid amide group (preferably having 1 to 20 carbon atoms, more preferably 1 to 10 carbon atoms, and particularly preferably 1 to 6 carbon atoms; and examples include a diethylphosphoric acid amide group and a phenylphosphoric acid amide group), a hydroxyl group, a mercapto group, a halogen atom (examples include a fluorine atom, a chlorine atom, a bromine atom, and an iodine atom), a cyano group, a nitro group, a hydroxamic acid group, a sulfino group, a hydrazino group, an imino group, an azo group, a heterocyclic group (preferably a heterocyclic group having 1 to 30 carbon atoms and more preferably 1 to 12 carbon atoms, and, for example, a heterocyclic group having a heteroatom such as a nitrogen atom, an oxygen atom, or a sulfur atom; and examples include an imidazolyl group, a pyridyl group, a quinolyl group, a furyl group, a piperidyl group, a morpholino group, a benzoxazolyl group, a benzimidazolyl group, and a benzothiazolyl group), and a silyl group (preferably a silyl group having 3 to 40 carbon atoms, more preferably 3 to 30 carbon atoms, and particularly preferably 3 to 24 carbon atoms; and examples include a trimethylsilyl group and a triphenylsilyl group). These substituents may be further substituted with these substituents. Furthermore, in a case in which the group has two or more substituents, the substituents may be identical or different. If possible, the substituents may also be bonded to each other and form a ring.

Preferred examples of the substituent include an alkyl group which may have a substituent, an alkenyl group which may have a substituent, an alkynyl group which may have a substituent, an aryl group which may have a substituent, an alkoxy group which may have a substituent, an oxycarbonyl group which may have a substituent, an acyloxy group which may have a substituent, an acylamino group which may have a substituent, an amino group which may have a substituent, an alkoxycarbonylamino group which may have a substituent, a sulfonylamino group which may have a substituent, a sulfamoyl group which may have a substituent, a carbamoyl group which may have a substituent, an alkylthio group which may have a substituent, a sulfonyl group which may have a substituent, a ureido group which may have a substituent, a nitro group, a hydroxyl group, a cyano group, an imino group, an azo group, and a halogen atom. Particularly preferred examples include an alkyl group which may have a substituent, an alkenyl group which may have a substituent, an aryl group which may have a substituent, an alkoxy group which may have a substituent, an oxycarbonyl group which may have a substituent, an acyloxy group which may have a substituent, a nitro group, an imino group, and an azo group.

The aromatic heterocyclic group is preferably a group derived from a monocyclic or bicyclic heterocyclic ring. Examples of an atom other than carbon, which constitutes the aromatic heterocyclic group, include a nitrogen atom, a sulfur atom, and an oxygen atom. In a case in which the aromatic heterocyclic group has a plurality of ring-constituting atoms other than carbon, these atoms may be identical or different. Specific examples of the aromatic heterocyclic group include a pyridyl group, a quinolyl group, a thiophenyl group, a thiazolyl group, a benzothiazolyl group, a thiadiazolyl group, a quinolonyl group, a naphthalimidoyl group, a thienothiazolyl group, and a group derived from a heterocyclic ring of the following formulae.

L₃ represents a divalent linking group. Specific examples of the divalent linking group include structural units selected from the following Structural Unit Group G, and groups formed by a combination of the structural units.

### Structural Unit Group G

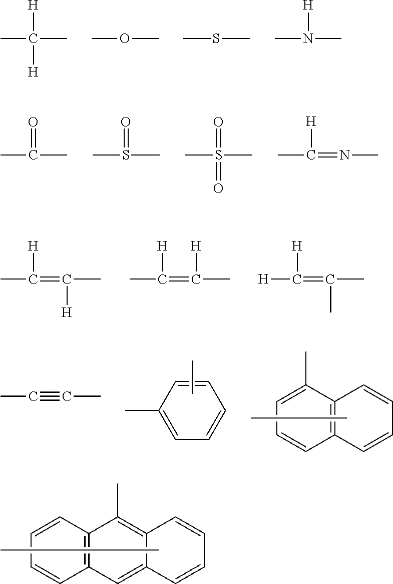

L₃ is preferably a single bond, or a divalent organic linking group composed of 1 to 50 carbon atoms, 0 to 8 nitrogen atoms, 0 to 25 oxygen atoms, 1 to 100 hydrogen atoms, and 0 to 10 sulfur atoms; more preferably a single bond, or a divalent organic linking group composed of 1 to 30 carbon atoms, 0 to 6 nitrogen atoms, 0 to 15 oxygen atoms, 1 to 50 hydrogen atoms, and 0 to 7 sulfur atoms; and particularly preferably a single bond, or a divalent organic linking group composed of 1 to 10 carbon atoms, 0 to 5 nitrogen atoms, 0 to 10 oxygen atoms, 1 to 30 hydrogen atoms, and 0 to 5 sulfur atoms.

L₃ is preferably an alkylene group (preferably an ethylene group), an ether group, an ester group, or a phenylene group.

According to the invention, in a case in which the other dichroic dye compound described above is incorporated, the content of the dye compound is preferably 5% to 50% by mass, and more preferably 10% to 40% by mass, with respect to the solid content mass of the dichroic dye composition. The other dichroic dye compound described above may be used singly, or two or more kinds thereof may be used in combination.

[Horizontal Aligning Agent]

The dichroic dye composition of the invention may include a horizontal aligning agent.

A horizontal aligning agent is a compound having an effect of promoting the dichroic dye compound of the invention to be substantially horizontally aligned.

Examples of the horizontal aligning agent include the compounds represented by General Formula (1) to (3) described in paragraphs [0253] to [0292] of JP2011-237513A, the disclosure of which is incorporated herein by reference.

By adding a horizontal aligning agent, the occurrence of alignment defects and surface unevenness at the light-absorbing anisotropic film/air interface can be suppressed, and the planar uniformity can be further enhanced. The term “horizontal alignment” means that the longitudinal direction of the dichroic dye compound is parallel to the horizontal surface of the light-absorbing anisotropic film; however, it is not required that the direction is strictly parallel. In the present specification, the horizontal alignment means an alignment in which the tilt angle formed by the longitudinal direction and the horizontal surface is less than 10 degrees. The tilt angle is preferably 5 degrees or less, more preferably 3 degrees or less, even more preferably 2 degrees or less, and most preferably 1 degree or less.

According to the invention, the content in the case of incorporating the horizontal aligning agent is preferably 0.01% to 20% by mass, more preferably 0.05% to 10% by mass, and particularly preferably 0.1% to 5% by mass, with respect to the mass of the dichroic dye compound of the invention. The horizontal aligning agent may be used singly, or two or more kinds thereof may be used in combination.

[Thermotropic Liquid Crystalline Polymer]

The dichroic dye composition of the invention may include a thermotropic liquid crystalline polymer.

Examples of the thermotropic liquid crystalline polymer include the main chain type polymers and side chain type polymers described in paragraphs [0020] to [0055] of JP2011-237513A, the disclosure of which is incorporated herein by reference.

According to the invention, the content in the case of incorporating the thermotropic liquid crystalline polymer is preferably 10% to 70% by mass, and more preferably 20% to 60% by mass, with respect to the solid content mass of the dichroic dye composition of the invention. The thermotropic liquid crystalline polymer may be used singly, or two or more kinds thereof may be used in combination.

[Polymerization Initiator]

In a case in which the dichroic dye composition of the invention includes another dichroic dye compound having a polymerizable group, it is preferable that the dichroic dye composition further includes a polymerization initiator.

The polymerization initiator used in the composition is preferably a photopolymerization initiator capable of initiating a polymerization reaction by ultraviolet irradiation.

Examples of the photopolymerization initiator include an α-carbonyl compound (described in U.S. Pat. No. 2,367,661A and U.S. Pat. No. 2,367,670A), acyloin ether (described in U.S. Pat. No. 2,448,828A), an α-hydrocarbon-substituted aromatic acyloin compound (described in U.S. Pat. No. 2,722,512A), polynuclear quinone compound (described in U.S. Pat. No. 3,046,127A and U.S. Pat. No. 2,951,758A), a combination of a triarylimidazole dimer and p-aminophenyl ketone (described in U.S. Pat. No. 3,549,367A), acridine and phenazine compounds (described in JP1985-105667A (JP-S60-105667A) and U.S. Pat. No. 4,239,850A), an oxadiazole compound (described in U.S. Pat. No. 4,212,970A), and an acylphosphine oxide compound (described in JP1988-40799B (JP-S63-40799B), JP1993-29234B (JP-H05-29234B), JP1998-95788A (JP-H10-95788A), and JP1998-29997A (JP-H10-29997A)).

According to the invention, the content in the case of incorporating the polymerization initiator is not particularly limited; however, the content is preferably 0.01% to 20% by mass, and more preferably 0.5% to 5% by mass, with respect to the mass of the other dichroic dye compound having a polymerizable group.

[Solvent]

It is preferable that the dichroic dye composition of the invention includes a solvent, from the viewpoint of workability and the like.

Here, since the dichroic dye composition of the invention includes the dichroic dye compound of the invention, the dichroic dye composition acquires satisfactory solubility in a solvent.

Specific examples of the solvent include ketones (for example, acetone, 2-butanone, methyl isobutyl ketone, cyclopentanone, and cyclohexanone), ethers (for example, dioxanc and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethylformamide and dimethylacetamide). These may be used singly, or two or more kinds thereof may be used in combination.

Among these, from the viewpoint of utilizing the effect of satisfactory solubility of the invention, it is preferable to use ketones.

[Light-Absorbing Anisotropic Film]

The light-absorbing anisotropic film of the invention is a light-absorbing anisotropic film formed using the dichroic dye composition of the invention described above.

An example of the method for producing the light-absorbing anisotropic film of the invention may be a method including at least:

1) a step of applying the dichroic dye composition of the invention on a substrate that will be described below, or on an alignment film formed on a substrate, and producing a coating film;

2) a step of heating the coating film at a temperature higher than or equal to the temperature at which the liquid crystalline components included in the coating film all undergo phase transition to a liquid crystal phase; and

3) a step of cooling the heated coating film to room temperature,

in this order.

In the step of 1), a dichroic dye composition including at least one dichroic dye compound of the invention as a solution (coating liquid), and the coating liquid is applied on a surface to form a coating film.

Regarding the coating method, known conventional methods such as a spin coating method, a gravure printing method, a flexographic printing method, an inkjet method, a die-coating method, a slit die-coating method, a CAP coating method, and dipping, can be carried out. Usually, since a solution diluted with an organic solvent is applied, the solution is dried after being applied, and thus a coating film is obtained.

In the step of 2), the organic solvent and the like are evaporated from the applied composition, subsequently the coating film is heated, and the composition is thereby aligned.

The heating temperature is preferably set to a temperature higher than or equal to the temperature at which the liquid crystalline components included in the coating film all undergo phase transition to a liquid crystal phase. In this case, the temperature at which liquid crystalline components all undergo phase transition to a liquid crystal phase is the highest temperature among the phase transition temperatures of the liquid crystal phases of the various components of the composition, or in a case in which the components are compatibilized, the temperature becomes the phase transition temperature of the liquid crystal phase of the mixture. Furthermore, the dichroic dye composition may also be heated to the temperature described above, simultaneously with evaporating the organic solvent and the like from the applied composition.

In the step of 3), the heated film is cooled to room temperature, and the alignment state is immobilized. For the purpose of improving heat resistance and durability, a polymerizable monomer and a polymerization initiator may be added to the composition, and a polymerization reaction may be caused to proceed before Step (3) so as to cure the film.

A light-absorbing anisotropic film can be formed as described above.

The thickness of the light-absorbing anisotropic film is preferably 0.01 to 2 μm, more preferably 0.05 to 1 μm, and even more preferably 0.3 μm to 0.9 μm.

[Polarizing Element]

The polarizing element of the invention is a polarizing element having an alignment film; and the light-absorbing anisotropic film of the invention provided on the alignment film.

Furthermore, regarding the polarizing element of the invention, an embodiment having a base material, an alignment film, and the light-absorbing anisotropic film of the invention in this order is preferred.

[Alignment Film]

An alignment film included in the polarizing element of the invention may be any layer as long as the dichroic dye compound of the invention can be brought into a desired alignment state on the alignment film.

The alignment film can be provided by a technique such as a rubbing treatment of an organic compound (preferably, a polymer) on a film surface, oblique vapor deposition of an inorganic compound, formation of a layer having microgrooves, or accumulation of an organic compound (for example, ω-tricosanoic acid, dioctadecylmethylammonium chloride, or methyl stearate) according to the Langmuir-Blodgett method (LB film). Furthermore, an alignment film acquiring an aligning function by means of application of an electric field, application of a magnetic field, or light irradiation, is also known. Above all, in the invention, an alignment film formed by a rubbing treatment is preferred from the viewpoint of the ease of controlling the pretilt angle of the alignment film, and from the viewpoint of the uniformity of alignment, a photo-alignment film formed by light irradiation is also preferred.

<Rubbing Treatment-Alignment Film>

Polymer materials that are used for alignment films formed by a rubbing treatment are described in a large number of literatures, and a large number of commercial products are available. According to the invention, polyvinyl alcohol or polyimide, and derivatives thereof are preferably used. In regard to the alignment film, the description on page 43, line 24 to page 49, line 8 of WO01/88574A1 can be referred to. The thickness of the alignment film is preferably 0.01 to 10 μm, and more preferably 0.01 to 1 μm.

<Photo-Alignment Film>

Photo-alignment materials used for alignment films formed by light irradiation are described in a large number of literatures. According to the invention, preferred examples include the azo compounds described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B; the aromatic ester compounds described in JP2002-229039A; the maleimide and/or alkenyl-substituted nadimide compound, both having a photo-alignment unit, as described in JP2002-265541A and JP2002-317013A; the photo-crosslinkable silane derivatives described in JP4205195B and JP4205198B; and the photo-crosslinkable polyimides, polyamides, or esters described in JP2003-520878A, JP2004-529220A, and JP4162850B. Particularly preferred examples include azo compounds, photo-crosslinkable polyimides, polyamides, or esters.

A photo-alignment film formed from any one of the above-described materials is subjected to linear polarization or non-polarization irradiation, and thus a photo-alignment film is produced.

According to the present specification, “linear polarization irradiation” and “non-polarization irradiation” are operations intended for inducing a photoreaction of a photo-alignment material. The wavelength of the light used may vary depending on the photo-alignment material used, and the wavelength is not particularly limited as long as it is a wavelength needed for the photoreaction. Preferably, the peak wavelength of the light used for light irradiation is 200 nm to 700 nm, and more preferably, the light is ultraviolet radiation having a peak wavelength of light of 400 nm or less.

The light source used for light irradiation is a light source that is conventionally used, and examples include lamps such as a tungsten lamp, a halogen lamp, a xenon lamp, a xenon flash lamp, a mercury lamp, a mercury-xenon lamp, and a carbon arc lamp; various lasers [for example, a semiconductor laser, a helium-neon laser, an argon ion laser, a helium-cadmium laser, and an yttrium-aluminum-garnet (YAG) laser]; a light emitting diode; and a cathode ray tube.

Regarding the means for obtaining linear polarization, a method of using a polarizing plate (for example, an iodine polarizing plate, a dichroic dye polarizing plate, or a wire grid polarizing plate); a method of using a reflective polarizer that utilizes a prism-based element (for example, a Glan-Thompson prism) or the Brewster's angle; or a method of using light emitted from a laser light source having polarization can be employed. Furthermore, it is also acceptable to selectively radiate only a light having a necessary wavelength, using a filter, a wavelength conversion element, or the like.

Regarding the light radiated, in the case of linear polarization, a method of radiating light through the upper surface or the back surface of an alignment film vertically or at an inclination with respect to the surface of the alignment film is employed. The incidence angle of light may vary depending on the photo-alignment material; however, for example, the incidence angle is 0° to 90° (vertical) and preferably 40° to 900.

In a case of non-polarization, non-polarization irradiation is performed at an inclination with respect to the alignment film. The incidence angle thereof is 10° to 80°, preferably 20° to 60°, and particularly preferably 30° to 50°.

The irradiation time is preferably 1 minute to 60 minutes, and more preferably 1 minute to 10 minutes.

In a case where patterning is needed, a method of performing light irradiation using a photo mask for the number of times required for pattern production, or a method based on pattern inscription by means of laser light scanning can be employed.

[Substrate]

The substrate that may be provided for the polarizing plate of the invention can be selected according to the use of the light-absorbing anisotropic film, and for example, a polymer film can be used.

The light transmittance of the substrate is preferably 80% or higher. Furthermore, it is preferable to use an optically isotropic polymer film as the substrate. Regarding specific examples and preferred embodiments of the polymer, the description of paragraph [0013] of JP2002-22942A can be applied. Even for a polymer that is likely to exhibit birefringence, such as a polycarbonate or a polysulfone, which are well-known in the related art, such a polymer with an inhibited exhibition of birefringence by modifying the molecule described in WO00/26705A can also be used.

[Image Display Device]

The image display device of the invention is an image display device having the light-absorbing anisotropic film of the invention or the polarizing element of the invention.

The display element used in the image display device of the invention is not particularly limited, and examples include a liquid crystal cell, an organic electroluminescence (hereinafter, abbreviated to “EL”) display panel, and a plasma display panel.

Among these, the image display device is preferably a liquid crystal cell or an organic EL display panel, and more preferably a liquid crystal cell. That is, the image display device of the invention is preferably a liquid crystal display device using a liquid crystal cell as a display element, or an organic EL display device using an organic EL display panel as a display element; and more preferably a liquid crystal display device.

[Liquid Crystal Display Device]

A liquid crystal display device as an example of the image display device of the invention is a liquid crystal display device having the polarizing element of the invention described above and a liquid crystal cell.

According to the invention, between the polarizing plates provided on both sides of a liquid crystal cell, it is preferable to use the polarizing element of the invention as the polarizing plate on the front side, and it is more preferable to use the polarizing element of the invention as the polarizing plate on the front side and the polarizing plate the rear side.

In the following description, the liquid crystal cell that constitutes a liquid crystal display device will be described in detail.

<Liquid Crystal Cell>

The liquid crystal cell utilized in a liquid crystal display device is preferably a liquid crystal cell of a VA (Vertical Alignment) mode, an OCB (Optical Compensated Bend) mode, an IPS (In-Plane-Switching) mode, or a TN (Twisted Nematic) mode; however, the liquid crystal cell is not limited to these.

In a liquid crystal cell of the TN mode, rod-shaped liquid crystalline molecules are substantially horizontally aligned at the time of no voltage application, and the rod-shaped liquid crystalline molecules are twist-aligned at 60° to 120°. Liquid crystal cells of the TN mode are utilized most frequently as color TFT liquid crystal display devices, and the liquid crystal cells are described in a large number of literatures.

In a liquid crystal cell of the VA mode, rod-shaped liquid crystalline molecules are substantially vertically aligned at the time of no voltage application. Liquid crystal cells of the VA mode include (1) a liquid crystal cell of the VA mode in a narrow sense, in which rod-shaped liquid crystalline molecules are substantially vertically aligned at the time of no voltage application, and the liquid crystalline molecules are substantially horizontally aligned at the time of voltage application (described in JP1990-176625A (JP-H02-176625A)), as well as (2) a liquid crystal cell in which the VA mode is designed as a multi-domain VA mode (MVA mode) for the purpose of viewing angle expansion (described in SID97, Digest of tech. Papers (proceedings) 28 (1997), 845), (3) a liquid crystal cell of a mode (n-ASM mode) in which rod-shaped liquid crystalline molecules are substantially vertically aligned at the time of no voltage application, and the liquid crystalline molecules are multi-domain twist-aligned at the time of voltage application (described in Proceedings 58 and 59 of Japanese Liquid Crystal Conference (1998)), and (4) a liquid crystal cell of a SURVIVAL mode (published at LCD International 98). The liquid crystal cell may also be any of PVA (Patterned Vertical Alignment) type, Optical Alignment type, and PSA (Polymer-Sustained Alignment) type. The details of these modes are described in detail in JP2006-215326A and JP2008-538819A.

In a liquid crystal cell of the IPS mode, rod-shaped liquid crystal molecules are aligned substantially parallel to the substrate, and as an electric field parallel to the substrate surface is applied, the liquid crystal molecules respond planarly. In the IPS mode, the display becomes a black display in a state of no electric field application, and the absorption axes of a pair of an upper polarizing plate and a lower polarizing plate orthogonally intersect each other. A method of improving the viewing angle by reducing light leakage at the time of black display in a tilted direction using an optical compensation sheet is disclosed in JP1998-54982A (JP-H10-54982A), JP1999-202323A (JP-H11-202323A), JP1997-292522A (JP-H09-292522A), JP1999-133408A (JP-H11-133408A), JP1999-305217A (JP-H11-305217A), JP1998-307291A (JP-H10-307291A), and the like.

[Organic EL Display Device]

Regarding an organic EL display device as an example of the image display device of the invention, for example, an embodiment in which the polarizing element of the invention, a plate having a W4 function (hereinafter, also referred to as “λ/4 plate”), and an organic EL display panel in this order from the viewer's side may be suitably mentioned.

Here, the “plate having λ/4 function” refers to a plate having a function of converting linear polarization at a particular wavelength into circular polarization (or converting circular polarization into linear polarization), and specific examples of an embodiment in which the λ/4 plate has a single layer structure include a stretched polymer film, and a retardation film obtained by providing an optically anisotropic layer having a λ/4 function on a support. Regarding an embodiment in which the λ/4 plate has a multilayer structure, specifically, a broadband λ/4 plate obtained by laminating a λ/4 plate and a λ/2 plate may be mentioned.

An organic EL display panel is a display panel configured using an organic EL element obtained by interposing an organic light emitting layer (organic electroluminescence layer) between electrodes (between a cathode and an anode). The configuration of the organic EL display panel is not particularly limited, and any known configuration is employed.

### EXAMPLES

Hereinafter, the invention will be described in more detail by way of Examples. The materials, amount of use, proportion, treatments, procedures, and the like disclosed in the following Examples can be modified as appropriate as long as the purport of the invention is maintained. Therefore, the scope of the invention is not to be limitedly construed based on the Examples described below.

[Synthesis of Dichroic Dye Compound]

The dichroic dye compounds described in Examples and Comparative Examples were synthesized by the following route.

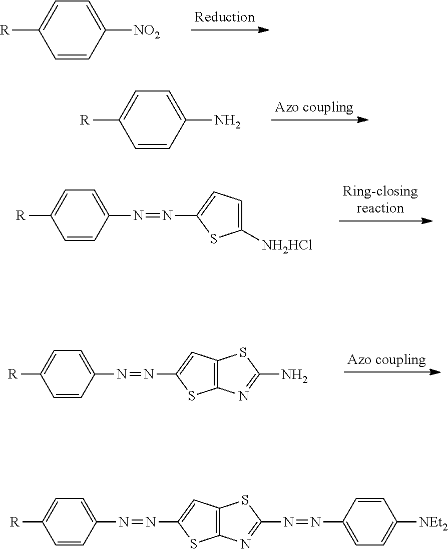

Compound (1) was synthesized according to the following steps.

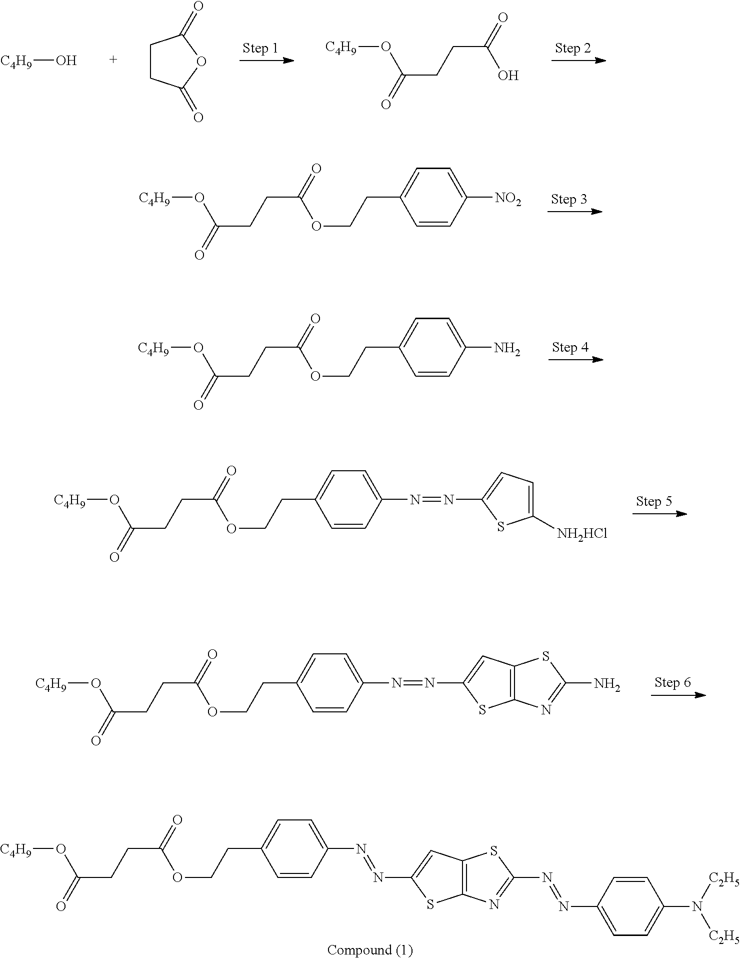

<Step 1 to Step 3>

14.8 g (200 mmol) of 1-butanol was mixed with 20.0 g (200 mmol) of succinic anhydride, the temperature was set at an external temperature of 105° C., and the mixture was stirred for one hour.

The temperature was lowered to room temperature, 200 ml of toluene and 2 ml of N,N-dimethylformamide (DMF) were added to the reaction system, and the reaction system was cooled with ice water. The internal temperature of the reaction system was maintained at 15° C. or lower, and 29.2 ml (210 mmol) of thionyl chloride was added dropwise thereto. After completion of the dropwise addition, the reaction system was stirred for 30 minutes while the temperature was maintained at 15° C. or lower.

Next, the reaction system was set at an external temperature of 40° C., and any excess thionyl chloride was distilled off under reduced pressure. After the distillation, 200 ml of ethyl acetate and 33.6 g (200 mmol) of 2-(4-nitrophenyl)ethanol were added to the system, and the mixture was cooled with ice water. While the internal temperature was maintained at 15° C. or lower, 21.2 g (210 mmol) of triethylamine was added dropwise to the reaction system.

After completion of the dropwise addition, ice water was removed, and the system was stirred for 30 minutes at room temperature. Subsequently, the system was subjected to a partition treatment using ethyl acetate and water, and the organic layer was washed three times with water.

The organic layer was dried over sodium sulfate and concentrated, and thus, a brown oil (a) was obtained.

Separately, 83.0 g (1.8 mol) of powdered Fe, 10.0 g (187 mmol) of ammonium chloride, 240 ml of 2-propanol, and 100 ml of water were mixed, and the mixture was refluxed at an external temperature of 105° C. To this refluxed system, the brown oil (a) dissolved in 100 ml of 2-propanol was added dropwise. After the dropwise addition, the mixture was allowed to react for 30 minutes under reflux. The temperature was lowered to room temperature, and then iron was eliminated by Celite filtration. The filtrate was partitioned with ethyl acetate and water, and the organic layer was washed three times with water.

The organic layer was dried over sodium sulfate and then concentrated. The concentrate was purified using a column, and thus 40.4 g of an intended aniline derivative was obtained (yield of three steps: 69%).

NMR (nuclear magnetic resonance) data (DMSO-d6) δ: 0.88 (t, 3H), 1.32 (m, 2H), 1.54 (m, 2H), 2.50 (s, 4H), 2.68 (t, 2H), 4.10 (t, 2H), 4.20 (t, 2H), 4.80 (brs, 2H), 6.50 (d, 2H), 6.90 (d, 2H)

<Step 4>

2-Aminothiophene was synthesized from 2-nitrothiophene (manufactured by Wako Pure Chemical Industries, Ltd.) according to a method described in the literature (Journal of Medicinal Chemistry, 2005, Vol. 48, p. 5794).

8.8 g (30 mmol) of the aniline derivative obtained in Step 3 was added to 10 ml of 12 mol/L hydrochloric acid and 20 ml of water, and the mixture was cooled so as to obtain an internal temperature of 0° C. or lower. 15 ml of an aqueous solution of 2.3 g of sodium nitrite (manufactured by Wako Pure Chemical Industries, Ltd.) was added dropwise to the mixture. The mixture was stirred for one hour at an internal temperature of 0° C., and thus a diazonium solution was prepared.

Next, the diazonium solution prepared as described above was added dropwise to 50 ml of an aqueous solution of 4.5 g (33 mmol) of 2-aminothiophene at an internal temperature of 0° C. The reaction liquid was warmed to room temperature and then was stirred for 2 hours.

A solid precipitated therefrom was separated by filtration and dried, and thus 9.7 g of an intended product as an orange-colored solid was obtained.

NMR data (DMSO-d6) δ: 0.88 (t, 3H), 1.32 (m, 2H), 1.54 (m, 2H), 2.50 (s, 4H), 2.68 (t, 2H), 4.10 (t, 2H), 4.20 (t, 2H), 6.20 (d, 1H), 7.10 (d, 1H), 7.54 (d, 2H), 8.21 (d, 2H), 12.0 (s, 1H)

<Step 5>

8.8 g (20 mmol) of the orange-colored solid obtained in Step 4 was suspended and dissolved in 100 ml of acetic acid, and 2.4 g (30 mmol) of sodium thiocyanate was added thereto at room temperature. The mixture was cooled with water, and while the internal temperature was maintained at 20° C. or lower, 3.2 g (40 mmol) of bromine was added dropwise thereto.

The mixture was stirred for 2 hours at room temperature, and then 100 ml of water was added to the mixture. A solid thus obtained was separated by filtration and dried. Thus, 7.4 g of an intended product as a red solid was obtained.

NMR data (DMSO-d6) δ: 0.88 (t, 3H), 1.32 (m, 2H), 1.54 (m, 2H), 2.50 (s, 4H), 2.68 (t, 2H), 4.10 (t, 2H), 4.20 (t, 2H), 6.9 (s, 2H), 7.15 (s, 1H), 7.50 (d, 2H), 8.20 (d, 2H), 12.0 (s, 1H)

<Step 6>

4.6 g (10.0 mmol) of the red solid obtained in Step 5 was added to 6 ml of hydrochloric acid and 6 ml of acetic acid, and 5 ml of an aqueous solution of 0.72 g (10.5 mmol) of sodium nitrite was added dropwise to the mixture at 0° C. or lower under ice cooling. The mixture was stirred for one hour, subsequently 0.52 mg of amidosulfuric acid was added thereto, and a diazonium solution was obtained.

While a solution of 1.5 g of N,N-diethylaniline in 10 ml of methanol was maintained at 0° C. or lower, the diazonium solution was added dropwise to the solution. The temperature was lowered to room temperature, the mixture was stirred for one hour, and then 30 ml of water was added thereto. A solid thus obtained was separated by filtration. The solid was purified using a column, and 1.1 g of Compound (1) as a dark purple solid represented by Formula (1) was obtained.

NMR data (CDCl₃) δ: 0.88 (t, 3H), 1.20 (t, 6H), 1.32 (m, 2H), 1.54 (m, 2H), 2.50 (s, 4H), 2.68 (t, 2H), 3.65 (d, 4H), 4.10 (t, 2H), 4.20 (t, 2H), 6.75 (d, 2H), 7.38 (d, 2H), 7.82 (d, 2H), 7.96 (d, 2H), 7.98 (s, 1H)

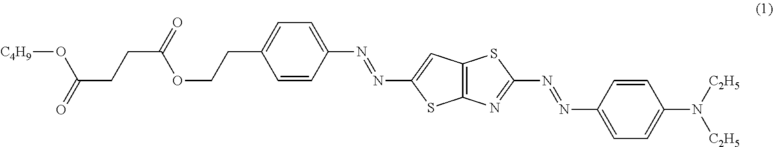

### Example 2

Compound (2) represented by Formula (2) was synthesized by a method similar to that used for Compound (1), except that the aniline derivative of Compound (1) was changed to a corresponding aniline derivative.

NMR data (CDCl₃) δ: 0.86 (t, 9H), 1.10-1.67 (m, 16H), 2.67 (t, 3H), 3.04 (t, 2H), 3.51 (q, 4H), 4.10 (m, 2H), 6.75 (d, 2H), 7.32 (d, 2H), 7.80 (d, 2H), 7.92 (s, 1H), 7.95 (d, 2H)

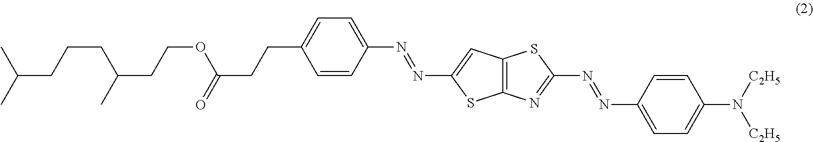 [SMILES: CCN(CC)c1ccc(/N=N/c2nc3sc(/N=N/c4ccc(CCC(=O)OCCC(C)CCCC(C)C)cc4)cc3s2)cc1]

### Example 3

Compound (3) represented by Formula (3) was synthesized by a method similar to that used for Compound (1), except that the aniline derivative of Compound (1) was changed to a corresponding aniline derivative.

NMR data (CDCl₃) δ: 0.88 (t, 6H), 1.10-1.58 (m, 14H), 2.24 (m, 1H), 3.04 (t, 2H), 3.51 (q, 4H), 4.34 (t, 2H), 6.75 (d, 2H), 7.32 (d, 2H), 7.80 (d, 2H), 7.92 (s, 1H) 7.95 (d, 2H)

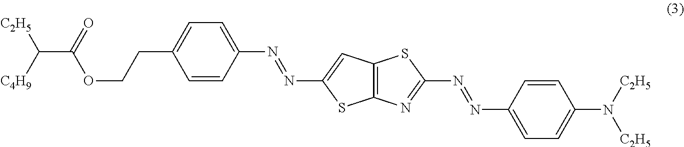

### Example 4

Compound (4) represented by Formula (4) was synthesized by a method similar to that used for Compound (1), except that the aniline derivative of Compound (1) was changed to a corresponding aniline derivative.

NMR data (CDCl₃) δ: 0.86 (t, 9H), 1.12 (m, 2H)), 1.26 (t, 6H), 1.49-1.70 (m, 6H), 2.62 (s, 4H), 3.04 (t, 2H), 3.51 (q, 4H), 4.10 (m, 2H), 4.34 (t, 2H), 6.75 (d, 2H), 7.32 (d, 2H), 7.80 (d, 2H), 7.92 (s, 1H) 7.95 (d, 2H)

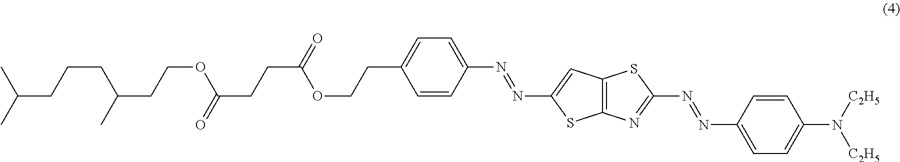 [SMILES: CCN(CC)c1ccc(/N=N/c2nc3sc(/N=N/c4ccc(CCOC(=O)CCC(=O)OCCC(C)CCCC(C)C)cc4)cc3s2)cc1]

### Example 5

Compound (5) represented by Formula (5) was synthesized by a method similar to that used for Compound (1), except that the aniline derivative of Compound (1) was changed to a corresponding aniline derivative.

NMR data (CDCl₃) δ: 0.86 (t, 3H), 1.32 (t, 6H), 1.60-1.88 (m, 10H), 2.32 (t, 2H), 3.51 (q, 4H), 4.14 (t, 2H), 4.40 (t, 2H), 6.75 (d, 2H), 7.90 (d, 2H), 7.94 (d, 2H), 8.00 (s, 1H), 8.17 (d, 2H)

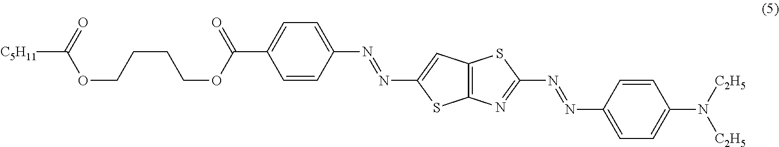

### Comparative Example 1

Compound (6) represented by Formula (6) was synthesized by a method similar to that used for Compound (1), except that the aniline derivative of Compound (1) was changed to a corresponding aniline derivative.

NMR data (CDCl₃) δ: 0.88 (t, 3H), 1.20-1.40 (m, 24H), 1.60-1.7 (m, 2H), 2.65 (t, 2H), 3.51 (q, 4H), 6.75 (d, 2H), 7.30 (d, 2H), 7.80 (d, 2H), 7.09 (s, 1H), 7.95 (d, 2H)

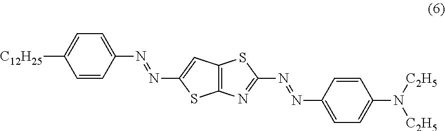

### Comparative Example 2

Compound (7) represented by Formula (7) was synthesized by a method similar to that used for Compound (1), except that the aniline derivative of Compound (1) was changed to a corresponding aniline derivative.

NMR data (CDCl₃) δ: 1.05 (t, 3H), 1.20-1.30 (t, 6H), 1.80-1.90 (m, 2H), 3.51 (q, 4H), 4.32 (t, 2H), 6.75 (d, 2H), 7.92 (d, 2H), 7.96 (d, 2H), 8.01 (s, 1H), 8.18 (d, 2H)

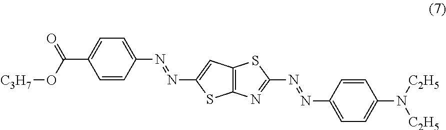

### Comparative Example 3

Compound (8) represented by Formula (8) was synthesized by a method similar to that used for Compound (1), except that the aniline derivative of Compound (1) was changed to a corresponding aniline derivative.

NMR data (CDCl₃) δ: 0.88 (t, 3H), 1.26-1.32 (m, 14H), 2.30 (t, 2H), 3.00 (t, 2H), 3.51 (q, 4H), 4.35 (t, 2H), 6.75 (d, 2H), 7.36 (d, 2H), 7.83 (d, 2H), 7.92 (s, 1H), 7.96 (d, 2H)

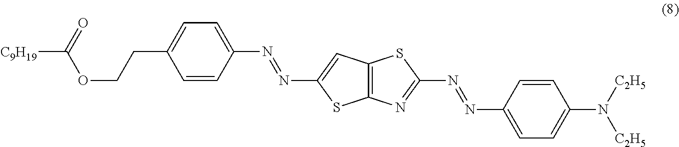

For Compounds (1) to (8) thus synthesized, solubility in cyclopentanone was measured. The results are presented in the following Table 1.

TABLE 1

| | Com- | | |
|---|---|---|---|
| | pound | | Solubility in |
| | No. | Structural Formula | cyclopentanone |
| Example 1 | (1) | 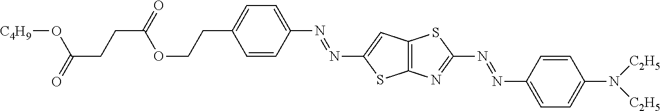 | 1.6% by mass |
| Example 2 | (2) | 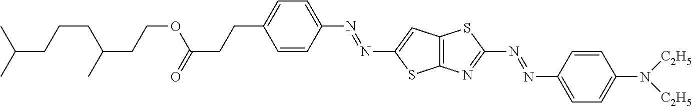 [SMILES: CCN(CC)c1ccc(/N=N/c2nc3sc(/N=N/c4ccc(CCC(=O)OCCC(C)CCCC(C)C)cc4)cc3s2)cc1] | 4.5% by mass |
| Example 3 | (3) | 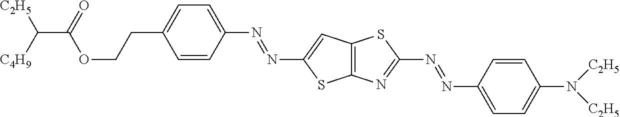 | 6.0% by mass |
| Example 4 | (4) | 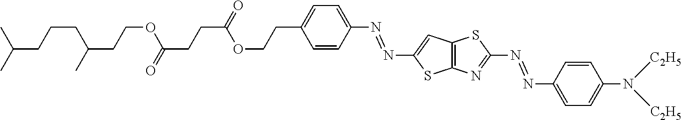 [SMILES: CCN(CC)c1ccc(/N=N/c2nc3sc(/N=N/c4ccc(CCOC(=O)CCC(=O)OCCC(C)CCCC(C)C)cc4)cc3s2)cc1] | 5.4% by mass |
| Example 5 | (5) | 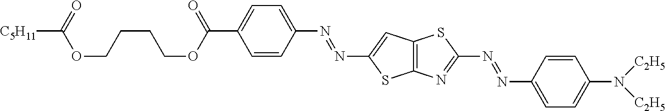 | 1.2% by mass |
| Comparative Example 1 | (6) | 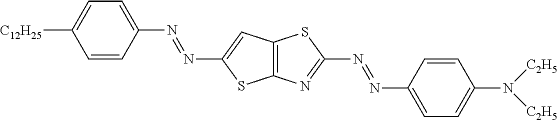 | 0.59% by mass |
| Comparative Example 2 | (7) | 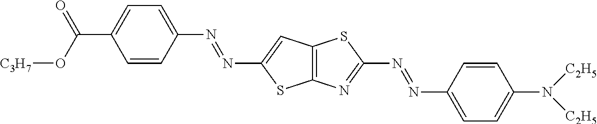 | 0.19% by mass |
| Comparative Example 3 | (8) | 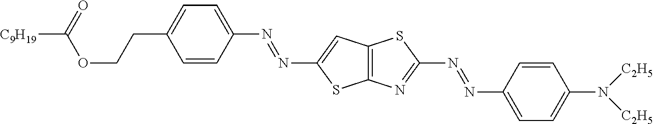 | 0.50% by mass |

From the results shown in Table 1, it was found that Compounds (1) to (5) synthesized in Examples 1 to 5 had their solubility in cyclopentanone improved to about 2 times to 10 times, compared to Compounds (6) to (8) synthesized in Comparative Examples 1 to 3, which do not correspond to the compound represented by Formula (I) described above. For example, from a comparison made between Compound (1) and Compound (8), it was found that Compound (1) had its solubility increased to 3 times or more by having two ester bonds.

### Example 6

A coating liquid for a light-absorbing anisotropic film (1) was obtained according to the composition of the following table.

The coating liquid thus obtained was applied by spin coating at 1,000 rpm for 30 seconds on a glass substrate provided with a polyvinyl alcohol alignment film (manufactured by Nissan Chemical Industries, Ltd., trade name: PVA-103) that had been subjected to a homogeneous alignment treatment by rubbing. The applied coating liquid was heated and aged for 30 seconds at a film surface temperature of 170° C., and a resulting film was cooled to room temperature. Furthermore, the film was heated for 30 seconds at 80° C. and was irradiated with ultraviolet radiation at 1,200 mJ at 80° C. in a nitrogen atmosphere. Thus, a light-absorbing anisotropic film was obtained.

In the light-absorbing anisotropic film thus formed, the absorption axis was parallel to the rubbing direction. The degree of polarization was 98%.

Composition of coating liquid for light-absorbing anisotropic film (1)

| | |
|---|---|
| Thermotropic liquid crystalline polymer (Polymer A shown below) | 52 parts by mass |
| Another dichroic dye compound (Compound B shown below) | 23 parts by mass |
| Dichroic dye compound (1) | 15 parts by mass |
| Dichroic dye compound (5) | 10 parts by mass |
| Fluorine-containing compound C | 0.3 parts by mass |
| Photopolymerization initiator (IRGACURE 819, manufactured by BASF SE) | 3.0 parts by mass |
| Cyclopentanone | 1900 parts by mass |

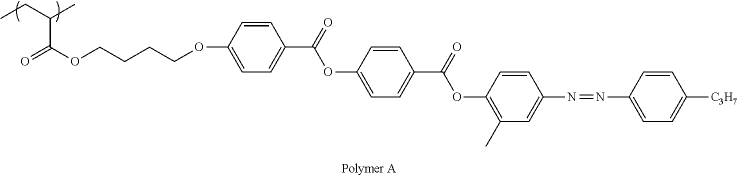

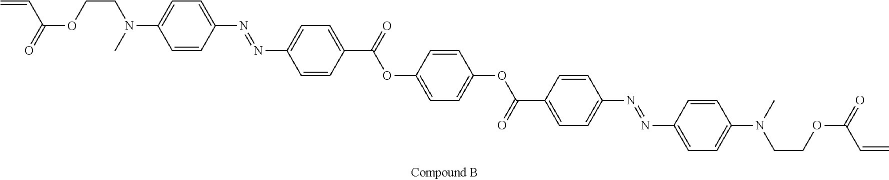 [SMILES: C=CC(=O)OCCN(C)c1ccc(/N=N/c2ccc(C(=O)Oc3ccc(OC(=O)c4ccc(/N=N/c5ccc(N(C)CCOC(=O)C=C)cc5)cc4)cc3)cc2)cc1]

### Reference Example 1

A light-absorbing anisotropic film was obtained by a method similar to that of Example 6, except that Compound (6) was used instead of Compound (1), Compound (7) was used instead of Compound (5), and chloroform was used instead of cyclopentanone. The degree of polarization of the light-absorbing anisotropic film thus obtained was 98%.

As a result, it was found that a light-absorbing anisotropic film formed in Example 6 using cyclopentanone as a solvent has a degree of polarization equivalent to that of the light-absorbing anisotropic film formed by using a dichroic dye compound known in the related art and using chloroform as a solvent.

1. A dichroic dye compound having a structure represented by Formula (I): 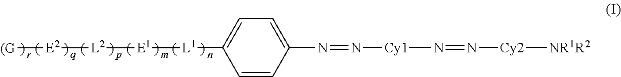
in Formula (I),
L¹ and L² each independently represent a divalent aliphatic hydrocarbon group which may have a substituent or a heteroatom;
E¹ and E² each independently represent an ester bond represented by —O(C═O)— or —(C═O)O—;
G represents a branched monovalent aliphatic hydrocarbon group;
n, m, p, q, and r each independently represent 0 or 1, and the sum of m, q, and r represents 2 or 3, provided that in a case in which the sum of m and q is 2, G represents a linear or branched monovalent aliphatic hydrocarbon group;
Cy1 and Cy2 each independently represent a divalent aromatic hydrocarbon group or a divalent aromatic heterocyclic group, both of which may have a substituent; and
R¹ and R² each independently represent an alkyl group which may have a substituent.

2. The dichroic dye compound according to claim 1, wherein in Formula (I), Cy1 and Cy2 each independently represent a phenylene group or a divalent aromatic heterocyclic group, both of which may have a substituent.

3. The dichroic dye compound according to claim 1, wherein in Formula (I), r is 1.

4. The dichroic dye compound according to claim 1, wherein in Formula (I), L¹ and L² each independently represent an alkylene group having 1 to 10 carbon atoms.

5. The dichroic dye compound according to claim 1, wherein in Formula (I), G has a methyl group or an ethyl group as a substituent, and the monovalent aliphatic hydrocarbon group is an alkyl group having 3 to 12 carbon atoms.

6. The dichroic dye compound according to claim 1, wherein in Formula (I), Cy1 represents a divalent aromatic heterocyclic group, and Cy2 represents a phenylene group.

7. The dichroic dye compound according to claim 1, wherein in Formula (I), Cy1 represents a divalent aromatic heterocyclic group in which two 5-membered heterocyclic rings are fused.

8. A dichroic dye composition comprising the dichroic dye compound according to claim 1.

9. The dichroic dye composition according to claim 8, further comprising another dichroic dye compound.

10. The dichroic dye composition according to claim 8, which comprises two or more kinds of said dichroic dye compounds.

11. The dichroic dye composition according to claim 8, further comprising a horizontal aligning agent.

12. A light-absorbing anisotropic film formed using the dichroic dye composition according to claim 8.

13. A polarizing element comprising:
an alignment film; and
the light-absorbing anisotropic film according to claim 12, provided on the alignment film.

14. An image display device comprising the light-absorbing anisotropic film according to claim 12.

15. An image display device comprising the polarizing element according to claim 13.

16. The dichroic dye compound according to claim 2, wherein in Formula (I), r is 1.

17. The dichroic dye compound according to claim 2, wherein in Formula (I), L¹ and L² each independently represent an alkylene group having 1 to 10 carbon atoms.

18. The dichroic dye compound according to claim 3, wherein in Formula (I), L¹ and L² each independently represent an alkylene group having 1 to 10 carbon atoms.

19. The dichroic dye compound according to claim 16, wherein in Formula (I), L¹ and L² each independently represent an alkylene group having 1 to 10 carbon atoms.

20. The dichroic dye compound according to claim 2, wherein in Formula (I), G has a methyl group or an ethyl group as a substituent, and the monovalent aliphatic hydrocarbon group is an alkyl group having 3 to 12 carbon atoms.
